(19) United States
(12) Patent Application Publication
(10) Pub. No.: US 2014/0347230 A1
(43) Pub. Date: Nov. 27, 2014

(54) Electromagnetic Wave Visualizing System

(71) Applicant: Hitachi, Ltd., Chiyoda-ku, Tokyo (JP)

(72) Inventors: Aya Ohmae, Tokyo (JP); Umberto Paoletti, Tokyo (JP); Yasuo Yahagi, Tokyo (JP)

(73) Assignee: Hitachi, Ltd., Chiyoda-ku, Tokyo (JP)

(21) Appl. No.: 14/367,123

(22) PCT Filed: Oct. 25, 2012
(86) PCT No.: PCT/JP2012/077588

§ 371 Date: Jun. 19, 2014

(30) Foreign Application Priority Data
Dec. 21, 2011 (JP) 2011-279895

(51) Int. Cl. G01R 29/08; G01R 29/10

(52) U.S. Cl. CPC G01R 29/0892; G01R 29/10; G01R 29/0814
USPC 343/703

(57) ABSTRACT

An electromagnetic wave visualizing system includes: an emission direction separation unit; a plurality of sensors, each detecting the energy of an electromagnetic wave emitted from the emission direction separation unit and outputting a sensing signal having strength corresponding to the detected energy; a processing unit capable of receiving the sensing signal from each of the sensors, the processing unit outputting a display signal when receiving the sensing signal from the sensor, the display signal containing information on the arrival direction of an electromagnetic wave with reference to a table based on position information on the sensor having transmitted the sensing signal; and a display unit capable of displaying the arrival directions of electromagnetic waves, the display unit displaying, when receiving the display signal, the arrival direction of an electromagnetic wave based on the electromagnetic wave arrival direction information obtained from the sensor position information contained in the display signal.

### TECHNICAL FIELD

The present invention relates to an electromagnetic wave visualizing system.

### BACKGROUND ART

Various electronic devices supporting social infrastructures have been operated with higher speeds in response to improved functionality. Thus, such electronic devices need to be designed such that electromagnetic noise from the devices does not cause electromagnetic interference on an increasing number of radio sets. In the event of electromagnetic interference, a survey needs to be quickly conducted on the spot. Hence, systems for visualizing the emission sources of electromagnetic noise in real time have been demanded.

Patent Literature 1 discloses, as a technique for visualizing electromagnetic waves, a system that scans a sensor for detecting an electromagnetic field strength, detects the position of the sensor from a camera image, and then superimposes the electromagnetic field strength and the sensor position on a display.

Patent Literatures 2 and 3 disclose techniques for performing arrival-direction estimating signal processing such as MUSIC (Multiple Signal Classification) and ESPRIT (Estimation of Signal Parameters via Rotational Invariance Techniques) on the signals of multiple antennas and depicting an electromagnetic field distribution on a display based on the information.

In Patent Literature 4, an anemometer is achieved by a lens and an antenna.

### CITATION LIST

### Patent Literatures

PLT 1: WO2009/028186

PLT 2: Japanese Patent Application Laid-Open No. 2005-207847

PLT 3: Japanese Patent Application Laid-Open No. 2011-53055

PLT 4: Japanese Patent Application Laid-Open No. 2008-122416

### SUMMARY OF INVENTION

### Technical Problem

In the technique of Patent Literature 1, a sensor scans a surface of a device and thus easily recognizes a part where electromagnetic noise is emitted. However, electromagnetic noise cannot be recognized in real time because of scanning, leading to difficulty in recognizing electromagnetic noise emitted like a burst. The technique described in Patent Literature 2 is likely to be affected by multipath. A reduction in the influence of multipath requires the stages of estimation in the arrival direction as in the technique of Patent Literature 3. This may reduce immediacy. In the technique described in Patent Literature 4, antennas are used for a receiving sensor. The antennas need to be mechanically operated in order to avoid interference between the antennas and increase a resolution. Thus, this system also reduces immediacy.

As described above, in the techniques of Patent Literatures 1 to 4, it is difficult to visualize the source of electromagnetic noise in real time. An object of the present invention is to provide an electromagnetic wave visualizing system that can visualize the emission source of electromagnetic noise in real time.

### Solution to Problem

This application includes multiple solutions to the problem. The present invention has a representative configuration:

An electromagnetic wave visualizing system includes:

an emission direction separation unit that changes the emission direction of an electromagnetic wave according to the incoming direction of the electromagnetic wave;

a plurality of sensors, each detecting the energy of an electromagnetic wave emitted from the emission direction separation unit and outputting a sensing signal having strength corresponding to the detected energy;

a processing unit capable of receiving the sensing signal from each of the sensors, the processing unit outputting a display signal when receiving the sensing signal from the sensor, the display signal including information on the arrival direction of an electromagnetic wave according to the sensor having transmitted the sensing signal; and

a display unit capable of displaying the arrival directions of electromagnetic waves, the display unit displaying the arrival direction of an electromagnetic wave when receiving the display signal.

### Advantageous Effect of Invention

According to the present invention, the emission source of electromagnetic waves can be visualized in real time.

### BRIEF DESCRIPTION OF DRAWINGS

FIG. 1 is a structural diagram of an electromagnetic wave visualizing system according to an embodiment of the present invention.

FIG. 2 illustrates a measurement example of the electromagnetic wave visualizing system according to the embodiment of the present invention.

FIG. 3 is an explanatory drawing of an electromagnetic wave lens (Luneburg lens) according to a first example of the present invention.

FIG. 4 shows an example of a set value for a relative dielectric constant of the Luneburg lens according to the first example of the present invention.

FIG. 5 shows an example of a measuring apparatus with a combination of the Luneburg lens and a sensor unit according to the first example of the present invention.

FIG. 6 is an overhead view of a low-reflective electromagnetic field sheet that is a sensor unit according to the first example of the present invention.

FIG. 7 is a cross-sectional view of the low-reflective electromagnetic field sheet illustrated in FIG. 6.

FIG. 8 is an explanatory drawing of a camera position correction according to the first example of the present invention.

FIG. 9 is an explanatory drawing of an emission direction separation unit having multiple electromagnetic wave lenses according to a second example of the present invention.

FIG. 10 is an explanatory drawing of an emission direction separation unit having multiple electromagnetic wave lenses according to a third example of the present invention.

FIG. 11 is an overhead view of a low-reflective electromagnetic field sheet acting as a sensor unit according to a fourth example of the present invention.

FIG. 12 is a grand pattern of the low-reflective electromagnetic field sheet according to the fourth example of the present invention.

FIG. 13 shows the wiring of row voltage sensors according to the fourth example of the present invention.

FIG. 14 shows the wiring of column voltage sensors according to the fourth example of the present invention.

FIG. 15 shows the principal part of a three-dimensional electromagnetic field measuring device according to a fifth example of the present invention.

### DESCRIPTION OF EMBODIMENTS

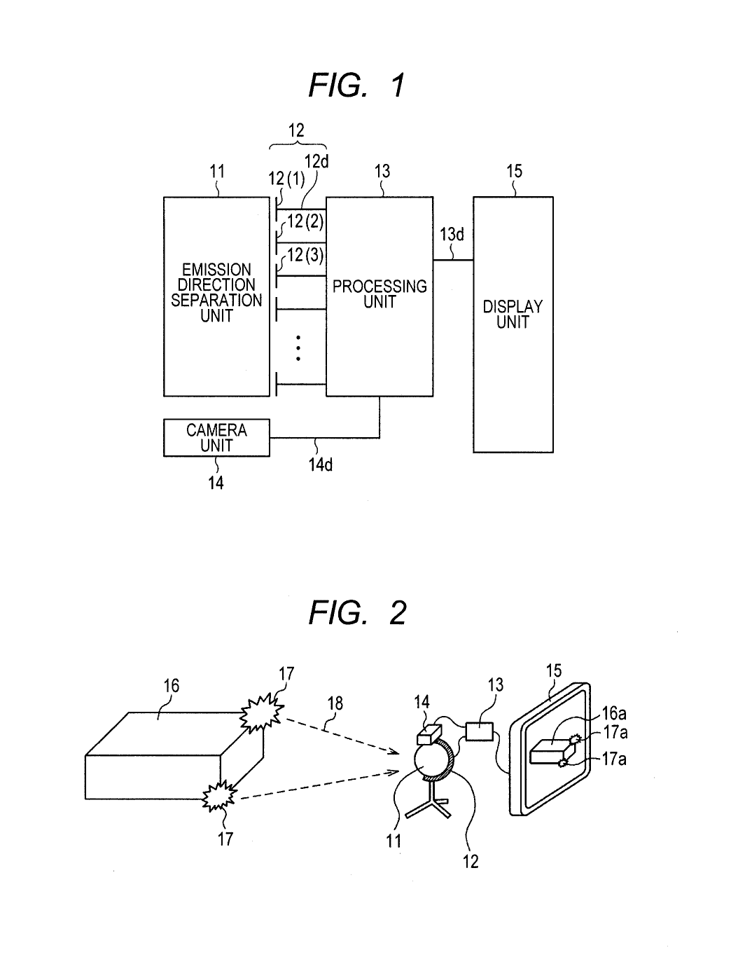

Referring to FIGS. 1 and 2, the configuration of an electromagnetic wave visualizing system according to an embodiment of the present invention will be described below. FIG. 1 is a structural diagram of the electromagnetic wave visualizing system according to the present embodiment. FIG. 2 illustrates a measurement example of the electromagnetic wave visualizing system according to the present embodiment.

As shown in FIG. 1, in the present embodiment, the electromagnetic wave visualizing system includes: an emission direction separation unit 11 having the function of separating the emission direction of an electromagnetic wave according to the arrival direction (incoming direction) of the electromagnetic wave; a sensor unit 12 including a plurality of sensors 12(1), 12(2), 12(3) . . . , each inducing a voltage according to the energy of electromagnetic waves; a camera unit 16 acting as an imaging unit that captures an image to be measured and outputs an image signal for the captured image; a processing unit 13 that processes the signals from the sensor unit 12 and the camera unit 14; and a display unit 15. The sensors 12(1), 12(2), 12(3) . . . have signal connections to the processing unit 13 via transmission lines 12d. The camera unit 14 has a signal connection to the processing unit 13 via a transmission line 14d. The display unit 15 has a signal connection to the processing unit 13 via a transmission line 13d.

The emission direction separation unit 11 includes, for example, an electromagnetic wave lens that focuses electromagnetic waves entering the lens and then changes the emission directions and positions of electromagnetic waves emitted from the lens, according to the arrival directions of incoming electromagnetic waves. Electromagnetic waves in multiple arrival directions are caused to converge at different positions, that is, the electromagnetic waves are focused at different positions. The lens will be specifically discussed later. The sensor unit 12 includes the sensors 12(1), 12(2), 12(3), . . . that detect the energy of electromagnetic waves emitted from the emission direction separation unit 11 and output sensing signals having strength corresponding to the detected energy. Thus, the sensor located at the focal position (focus) of electromagnetic waves entering the lens outputs the sensing signal. In other words, the sensors selectively output the sensing signals according to the focal position of electromagnetic waves entering the lens.

The processing unit 13 can receive the sensing signals from the respective sensors of the sensor unit 12 and has a table in which the sensor positions are associated with the arrival angles of electromagnetic waves, that is, arrival direction information on electromagnetic waves. When receiving the sensing signal from one of the sensors of the sensor unit 12, the processing unit 13 obtains, from position information on the sensor having transmitted the sensing signal, arrival direction information on electromagnetic waves according to a sensor position with reference to the table, and then the processing unit 13 outputs a display signal including the arrival direction information on the electromagnetic waves and strength information on the received sensing signal. Furthermore, the processing unit 13 receives an image signal for an image captured by the camera unit 14, generates a display signal by superimposing, on the image signal, the signal including the electromagnetic wave arrival direction information and the strength information on the sensing signal, and then outputs the display signal to the display unit 15.

The display unit 15 can display multiple noise positions. When receiving the display signal from the processing unit 13, the display unit 15 displays the position of an electromagnetic wave on a measuring object and the strength of the sensing signal, that is, the strength of the electromagnetic wave on, for example, an LCD (Liquid Crystal Display) based on the electromagnetic wave arrival direction information and the strength information on the sensing signal that are included in the display signal. Moreover, the display unit 15 displays the display signal received from the processing unit 13, thereby simultaneously displaying an image captured by the camera unit 14. As described above, the display unit 15 displays the information including the electromagnetic wave arrival direction information and the strength information on the sensing signal such that the information is superimposed on the image of the measuring object captured by the camera unit 14.

As illustrated in the example of FIG. 2, electromagnetic waves 18 generated from, for example, noise sources 17 on the measuring object 16 are separated through the electromagnetic wave lens 11 acting as the emission direction separation unit 11. In other words, the emission directions of the electromagnetic waves from the electromagnetic wave lens 11 are changed according to the incoming directions of the electromagnetic waves, and then the electromagnetic waves are caused to enter the sensor unit 12. In the sensor unit 12, the sensor with energy induced by incoming electromagnetic waves through the electromagnetic wave lens 11 outputs the sensing signal having strength corresponding to the induced energy. In the processing unit 13, a sensor position (number) where the sensing signal is outputted and the strength of the sensing signal are identified. The processing unit 13 contains the table in which the sensor positions (numbers) are associated with the arrival angles of electromagnetic waves. The arrival angle of an electromagnetic wave is obtained with reference to the table based on the position information on the sensor having outputted the sensing signal. In this way, position information on generated electromagnetic waves can be obtained on the measuring object according to the arrival angles of electromagnetic waves. Furthermore, the processing unit 13 receives the image signal of the image captured by the camera unit 14, generates the display signal by superimposing, on the image signal, the signal including the position information on generated electromagnetic waves in the arrival directions of the electromagnetic waves based on the sensor position information, that is, electromagnetic waves on the measuring object and the strength information on the sensing signal, that is, the strength information on electromagnetic waves, and then the processing unit 13 outputs the display signal to the display unit 15. The display unit 15 displays the display signal received from the processing unit 13 so as to display, on the image captured by the camera unit 14, the position of the noise source 17 and the level of noise on the measuring object 16, thereby achieving visualization of electromagnetic waves.

In the example of FIG. 2, the display unit 15 displays an image 16a of the measuring object 16 and also displays the position of an image 17a of the noise source 17 and the level of noise on the image. The level of noise is indicated by the size of the image 17a. The level of noise may be indicated by other methods, for example, colors on relative numerical display or numerical values on a screen.

When receiving the sensing signal from one of the sensors of the sensor unit 12, the processing unit 13 may be configured to output, if the received sensing signal is so strong as to reach at least a predetermined value, a display signal that includes only arrival direction information on electromagnetic waves according to the sensor having transmitted the sensing signal but does not include strength information on the received sensing signal. In this case, the display unit 15 displays the position of the sensor regardless of the strength of the sensing signal. For example, in the example of FIG. 2, the level of noise is displayed with a constant level regardless of the strength of the sensing signal.

### First Example

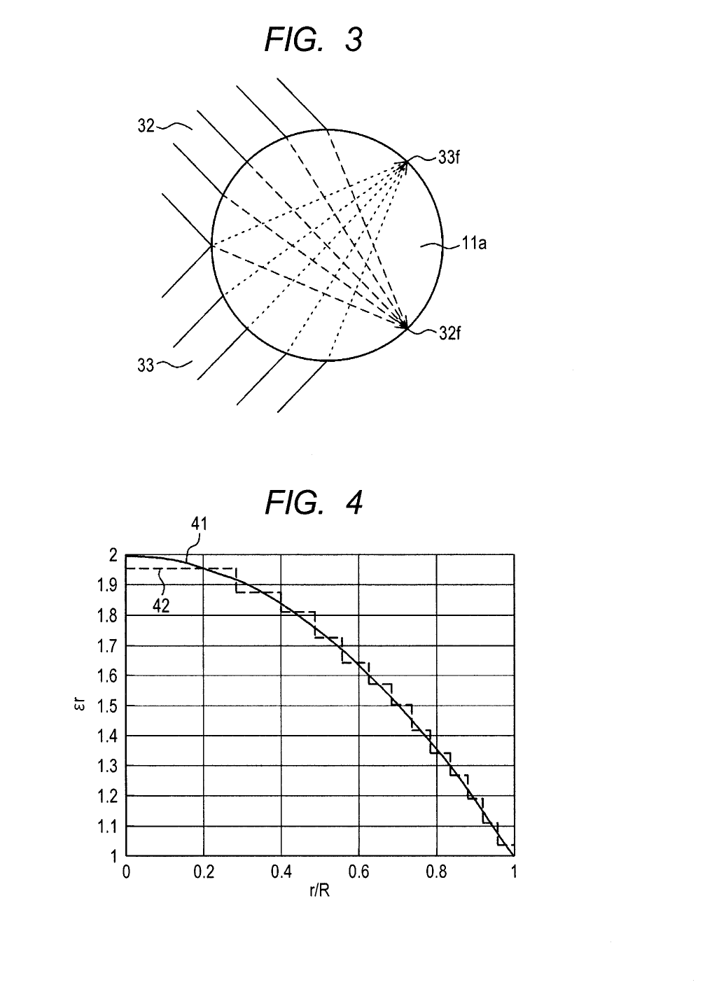

Referring to FIG. 3, a first example will be described below. In the first example, an electromagnetic wave lens in the emission direction separation unit 11 is a Luneburg lens. FIG. 3 is an explanatory drawing of the Luneburg lens according to the first example of the present invention. A Luneburg lens 11a, which is an electromagnetic wave lens, is a structure in which a sphere forming the lens has a relative dielectric constant of ∈r gradually changing from 1 to 2 from the outer periphery to the center. Electromagnetic waves entering the lens focus at a certain position on the surface of the lens according to an arrival angle.

For example, as shown in FIG. 3, if electromagnetic waves 32 and electromagnetic waves 33 enter the lens at different arrival angles, the electromagnetic waves 32 are caused to converge on a focus 32f while the electromagnetic waves 33 are caused to converge on a focus 33f. Electromagnetic waves in different arrival directions focus on different points and thus the arrival directions of the electromagnetic waves are identified by the focal positions of the electromagnetic waves.

The ideal value of the relative dielectric constant ∈r at a distance r from the center of the Luneburg lens 11a is expressed by the following formula: where 2R is the diameter of the lens.

$${ɛ}_{r} = 2 - {( \frac{r}{R} )}^{2} \qquad [ Formula 1 ]$$

The relative dielectric constant ∈ᵣ desirably changes on the Luneburg lens 11a in a continuous manner. Actually, as shown in FIG. 4, the Luneburg lens 11a is formed (designed) such that the relative dielectric constant ∈ᵣ discontinuously (gradually) changes at the distance r from the center of the lens 11a. FIG. 4 shows an example of an ideal value and an actual set value of a relative dielectric constant of the Luneburg lens according to the first example. The vertical axis indicates the relative dielectric constant ∈ᵣ while the horizontal axis indicates r/R. In FIG. 4, reference numeral 41 denotes an ideal value and reference numeral 42 denotes an actual set value. As r/R approaches 1, that is, the surface of the spherical lens, the relative dielectric constant ∈ᵣ approaches 1. As r/R approaches 0, that is, the center of the spherical lens, the relative dielectric constant ∈ᵣ approaches 2.

Moreover, the relative dielectric constant ∈ᵣ changes an effective dielectric constant with a hole formed on a certain material, thereby achieving the Luneburg lens 11a.

In the present example, the spherical Luneburg lens is used but the lens used as the emission direction separation unit 11 is not limited to a Luneburg lens. The lens may have any shapes as long as an emission direction separating function is provided according to the arrival directions of electromagnetic waves. For example, an aspheric lens is usable.

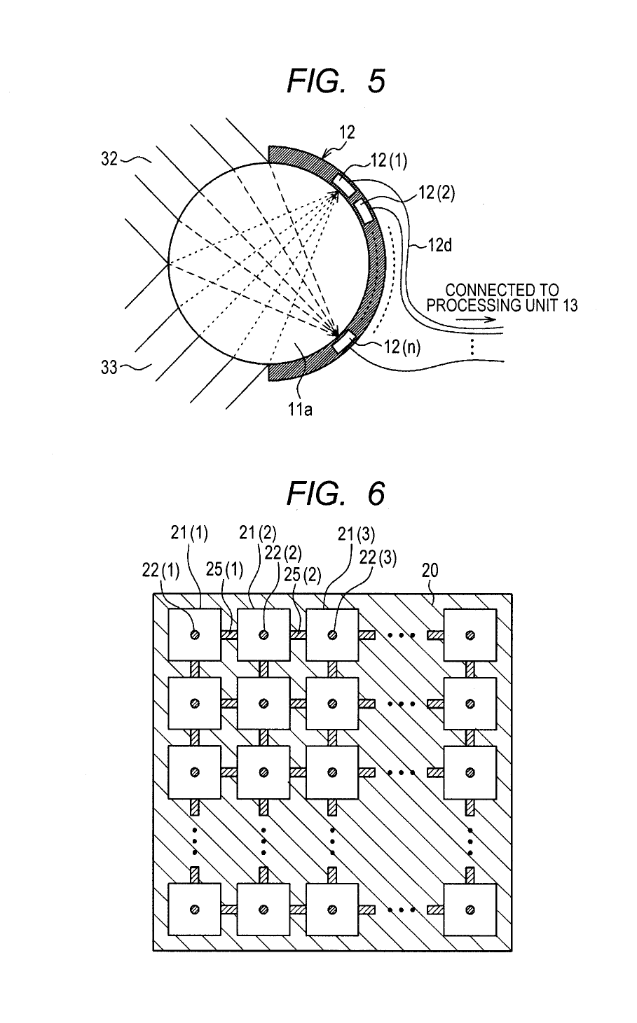

Referring to FIG. 5, an example of a measuring apparatus with a combination of the electromagnetic wave lens and the sensor unit will be described below. The left half (the left half in FIG. 5) of the spherical Luneburg lens 11a serves as an electromagnetic wave entry part while the right half of the lens is covered with the sensor unit 12. The electromagnetic waves 32 and the electromagnetic waves 33 entering the left-half electromagnetic wave entry part focus at different positions on the right-half spherical surface according to the incoming directions of the electromagnetic waves. The sensors 12(1), 12(2), . . . 12(n) are disposed at the focal positions of the Luneburg lens 11a, allowing the detection of the arrival directions of electromagnetic waves and the level of energy (the strength of electromagnetic waves). The signals of the sensors are transmitted to the processing unit 13 through the signal transmission lines 12d. In the example of FIG. 5, the electromagnetic waves 32 focus on the sensor 12(n) while the electromagnetic waves 33 focus on the sensor 12(1).

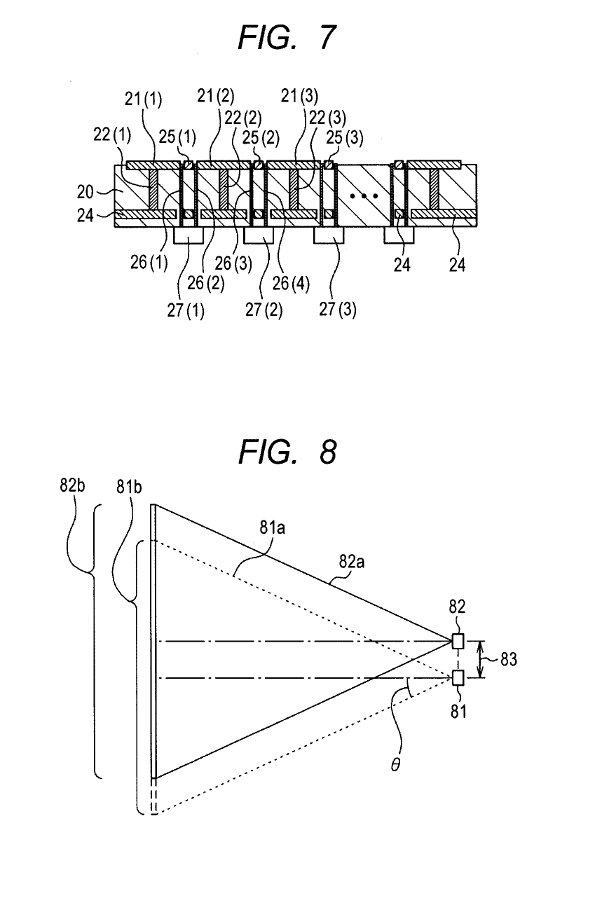

Referring to FIGS. 6 and 7, the sensor unit 12 according to the first example will be described below. FIG. 6 is an overhead view of a sheet low-reflective electromagnetic field sensor that is the sensor unit of the first example. FIG. 7 is a cross-sectional view of the low-reflective electromagnetic field sheet illustrated in FIG. 6. The low-reflective electromagnetic field sensor of the present example is realized by a mushroom-like metallic periodic structure as will be described later.

As shown in FIG. 6, a first layer on a surface of a plate dielectric 20 has periodically arranged metal patches 21. Specifically, the metal patches 21 are placed in a lattice pattern, that is, in a row direction (horizontal direction) and a column direction (vertical direction). For example, the metal patches 21(1), 21(2), 21(3) . . . are disposed in the row direction. The metal patches 21 are connected via resistors 25. A via 22 is provided at the center of the metal patch 21.

The metal patches 21 are sufficiently small relative to a wavelength λ of an electromagnetic wave to be measured. The length of one side of the metal patch 21 is ( 1/10)λ or less. For example, if the frequency of measured electromagnetic wave is 2.4 GHz, one side of the metal patch 21 is 12.5 mm in length. In the present example, the metal patch 21 is a square metal plate but is not limited to a square shape.

As shown in FIG. 7, a ground 24 that is a conductor serving as a second layer parallel to the first layer is provided near the back side of the dielectric 20, the ground 24 being substantially identical in size to the dielectric 20. The ground 24 is connected to the metal patch 21 via the conductor via 22 with the dielectric 20 interposed between the ground 24 and the metal patch 21. Specifically, the metal patch 21(1) is connected to the ground 24 via the via 22(1), the metal patch 21(2) is connected to the ground 24 via the via 22(2), and the metal patch 21(3) is connected to the ground 24 via the via 22(3).

As shown in FIG. 7, voltage sensors 27 on the back side of the dielectric 20 are provided for the respective resistors 25. A voltage sensor via 26 that is a conductor connected to the voltage sensor 27 is provided on each end of the resistor 25. The voltage sensor via 26 penetrates the dielectric 20 and the ground 24 and is connected to the voltage sensor 27. The ground 24 has a hole where the voltage sensor via 26 is inserted. This electrically disconnects the ground 24 and the voltage sensor via 26. Specifically, for example, voltage sensor vias 26(1) and 26(2) are provided on the respective ends of the resistor 25(1) and are connected to the voltage sensor 27(1). Moreover, voltage sensor vias 26(3) and 26(4) are provided on the respective ends of the resistor 25(2) and are connected to the voltage sensor 27(2).

The voltage sensor 27 detects a voltage induced across the resistor 25, through the voltage sensor vias 26. Specifically, for example, the voltage sensor 27(1) detects a voltage induced across the resistor 25(1), the voltage sensor 27(2) detects a voltage induced across the resistor 25 (2), and the voltage sensor 27(3) detects a voltage induced across the resistor 25(3). The voltage sensor 27 includes, for example, an amplifier, an AD converter, and a voltage measuring device.

When electromagnetic waves are emitted to one of the metal patches 21 constituting the low-reflective electromagnetic field sheet, a voltage is induced only across the resistor 25 connected to the irradiated metal patch 21. Thus, the arrival direction of electromagnetic waves can be identified by the position of the voltage sensor 27 connected to the resistor 25.

At this point, if the resistor 25 has a resistance of 377Ω like a wave impedance, the impedance of a space is matched to that of the sensor unit 12, allowing the sensor unit 12 to absorb the energy of electromagnetic waves without reflecting the electromagnetic waves.

Referring to FIG. 8, a camera position of the first example will be discussed below. FIG. 8 is an explanatory drawing of a camera position correction according to the first example.

A camera for capturing an image of the measuring object 16 is preferably disposed at the center of the lens (center position). However, the camera disposed at the center of the lens may interfere with a measurement of electromagnetic waves. Actually, the camera is disposed with a camera position difference 83 from the center of the lens like a camera 82. An actual image 82b captured by the camera 82 is deviated by the camera position difference 83 from an image 81b captured by the camera located at the center of the lens. Thus, a center position correction is performed by the camera position difference 83.

Moreover, the camera has a known maximum viewing angle of θ. As described above, arrival angle information on electromagnetic waves measured by the sensor unit 12 is obtained with reference to the table in which the positions of the sensor unit are associated with the arrival angle information on the electromagnetic waves.

The viewing angle of the camera 82 is joined to the viewing angles of electromagnetic field measurement results obtained by the lens unit 11 and the sensor unit 12. An image of the measuring object 16 is captured by the camera 82 with the joined viewing angles; meanwhile, electromagnetic waves are measured by the lens unit 11 and the sensor unit 12. Moreover, the processing unit 13 performs a center position correction by the camera position difference 83, and then both images are superimposed and displayed on the display unit 15, achieving visual analyses of electromagnetic waves.

The dielectric 20 is thin and is made of materials such as polyimide. The dielectric 20 can be bent with flexibility and thus allows the low-reflective electromagnetic field sheet to be easily attached along the spherical surface of the Luneburg lens 11a. Alternatively, a plate-like sensor may be divided along a lens.

In the present example, the voltage sensor 27 measures a voltage for detecting electromagnetic waves. Other devices such as a power measuring element may be used as long as the energy of electromagnetic waves can be detected.

Moreover, in the present example, the low-reflective electromagnetic field sensor includes the square metal patches 21 acting as electromagnetic wave absorbing devices. Nonreflective devices in any other shapes may be used as long as electromagnetic waves are absorbed and energy is generated between the devices. The sensor unit 12 and the processing unit 13, which are separated units, may be combined into a single unit.

In the configuration of the present example, the positions of generated electromagnetic waves are displayed while the energy level of electromagnetic waves is displayed. The energy level of electromagnetic waves may not be displayed, specifically, only the positions of generated electromagnetic waves with energy having a predetermined value or more may be displayed in this configuration.

The first example can achieve the following effects:

(1) The arrival direction of electromagnetic waves can be detected and displayed in real time.
(2) The energy level of electromagnetic waves can be detected and displayed in real time.
(3) Since the Luneburg lens is used as the emission direction separation unit, incoming electromagnetic waves can be easily focused.
(4) The flexible low-reflective electromagnetic field sheet is used as the sensor unit and thus can be easily attached to the Luneburg lens.
(5) The low-reflective electromagnetic field sensor including the metal patches and resistors allows efficient absorption of incoming electromagnetic waves. Additionally, if the resistance is 377Ω like a wave impedance, the energy of incoming electromagnetic waves can be more efficiently absorbed.

### Second Example

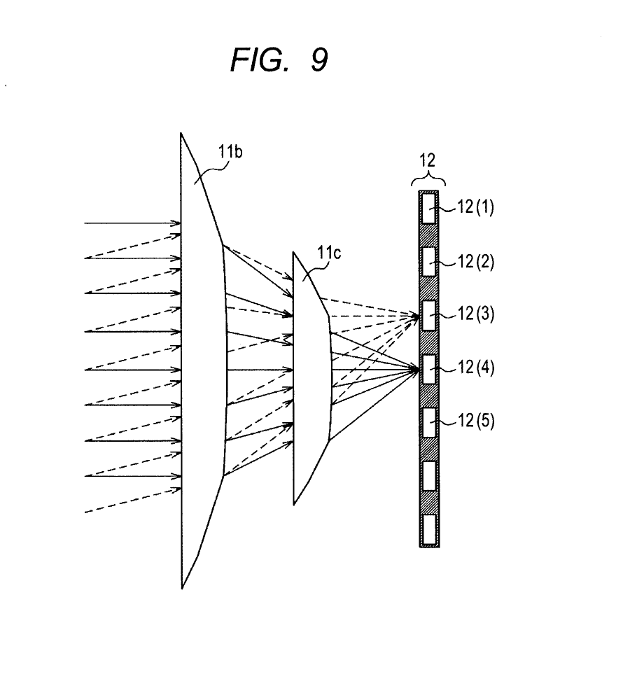

Referring to FIG. 9, a second example will be discussed below. An aspheric lens is used as an emission direction separation unit 11. FIG. 9 is an explanatory drawing of an emission direction separation unit having multiple electromagnetic wave lenses according to the second example. In this example, the electromagnetic wave lenses are aspheric lenses 11b and 11c. The shape of a sensor unit 12 is not limited to a flat shape. Other configurations are identical to those of the first example and thus the explanation thereof is omitted.

As shown in FIG. 9, the two aspheric lenses 11b and 11c are arranged in series along the incoming direction of electromagnetic waves. The energy of electromagnetic waves collected by the large-diameter aspheric lens 11b further converges through the aspheric lens 11c and then is transmitted to the sensor unit 12.

In the example of FIG. 9, electromagnetic waves (indicated by solid lines) entering the aspheric lens 11b in the horizontal direction are caused to converge through the aspheric lens 11b and enter the aspheric lens 11c to further converge through the aspheric lens 11c, coming into focus on a sensor 12(4). Electromagnetic waves (broken lines) diagonally entering the aspheric lens 11b are caused to converge through the aspheric lens 11b and enter the aspheric lens 11c to further converge through the aspheric lens 11c, coming into focus on a sensor 12(3). Any number of aspheric lenses may be provided in any shapes as long as the energy level is receivable by the sensor 12.

Thus, the emission direction separation unit 11 of the second example is effective for providing lenses with larger diameters so as to detect electromagnetic waves with higher sensitivity. Since the energy of electromagnetic waves at a focal position is determined by the effective opening area of the lens, a larger lens can collect larger energy. The provision of multiple lenses can efficiently collect energy.

### Third Example

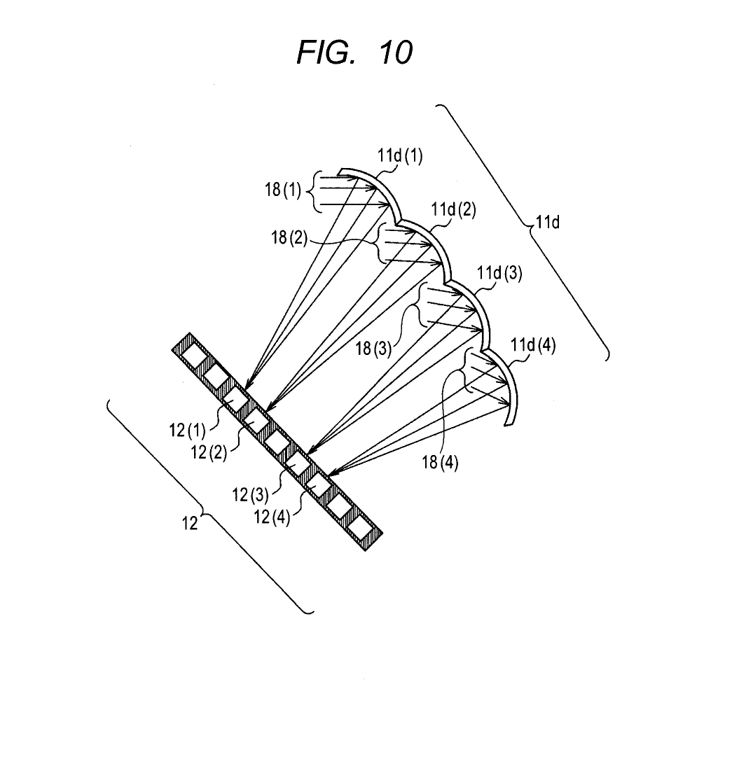

Referring to FIG. 10, a third example will be described below. Antennas are used as an emission direction separation unit 11. FIG. 10 is an explanatory drawing of the emission direction separation unit in which the parabolic antennas of the third example are used. The shape of a sensor unit 12 is not limited to a flat shape. Other configurations are identical to those of the first example and thus the explanation thereof is omitted.

The function of separating and amplifying electromagnetic waves can be achieved not only by lenses but also by antennas such as parabolic antennas. As shown in FIG. 10, in the third example, a plurality of parabolic antennas 11d(1), 11d(2), 11d(3), and 11d(4) are placed in an array so as to directly receive electromagnetic waves from the emission source of electromagnetic waves. The parabolic antennas are set with various angles so as to vary the focal positions of reflected waves relative to the arrival directions of electromagnetic waves.

In the example of FIG. 10, the antenna 11d(1) reflects horizontally incoming electromagnetic waves 18(1) in FIG. 10 and emits the electromagnetic waves 18(1) into focus on a sensor 12(1), the antenna 11d(2) reflects electromagnetic waves 18(2) incoming slightly downward relative to the electromagnetic waves 18(1) and emits the electromagnetic waves 18(2) into focus on a sensor 12(2), the antenna 11d(3) reflects electromagnetic waves 18(3) incoming slightly downward relative to the electromagnetic waves 18(2) and emits the electromagnetic waves 18(3) into focus on a sensor 12(3), and the antenna 11d(4) reflects electromagnetic waves 18(4) incoming slightly downward relative to the electromagnetic waves 18(3) and emits the electromagnetic waves 18(4) into focus on a sensor 12(4).

The sensors 12(1), 12(2), 12(3), and 12(4) are disposed at the focal positions of the parabolic antennas so as to detect only electromagnetic waves in a specific direction and estimate the arrival direction of the electromagnetic waves.

### Fourth Example

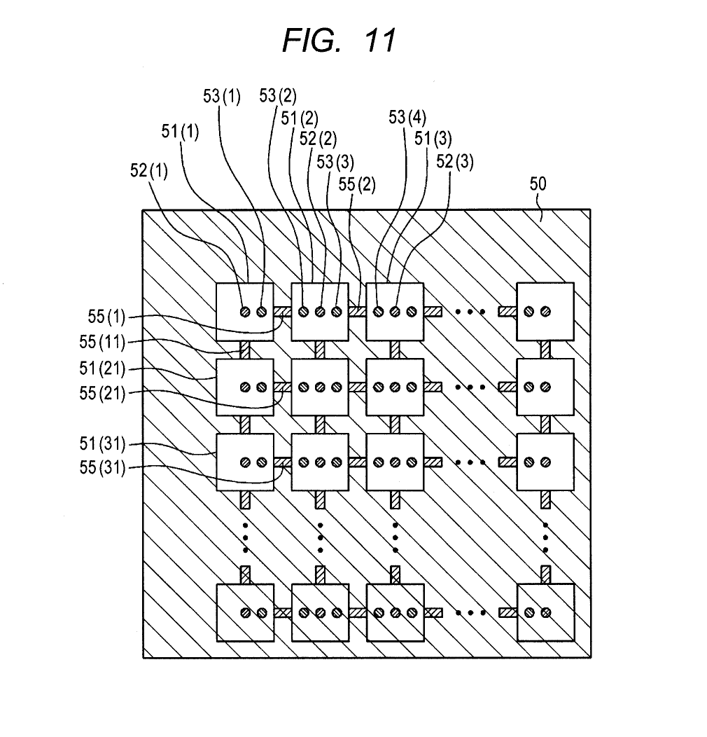

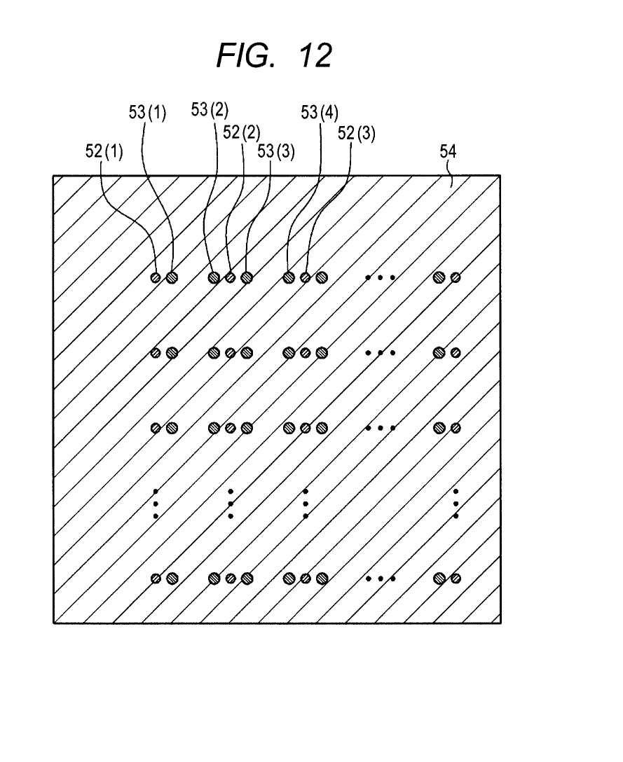

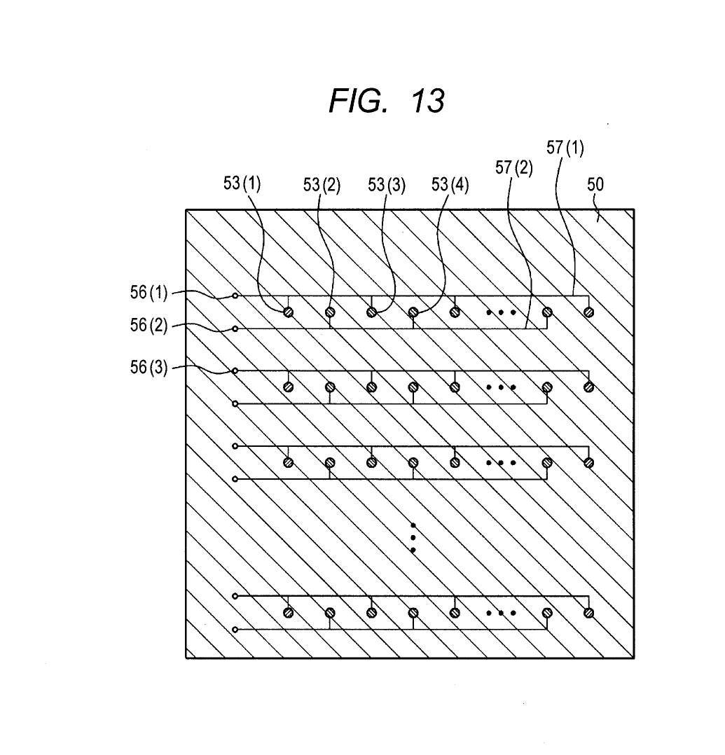

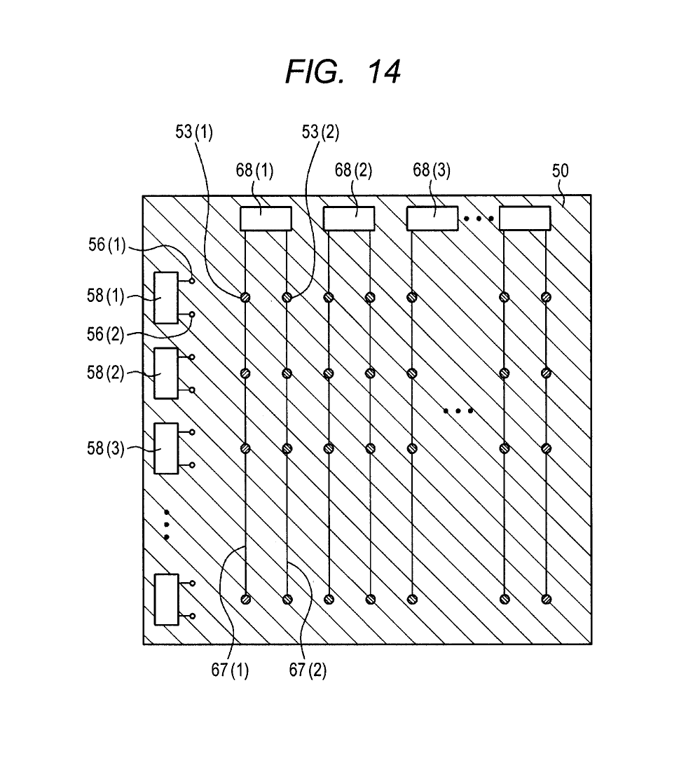

Referring to FIGS. 11 to 14, a fourth example will be discussed below. Voltage sensors are provided in each row and each column as a sensor unit 12. FIG. 11 is an overhead view of a low-reflective electromagnetic field sheet acting as the sensor unit of the fourth example. FIG. 12 is a grand pattern of the low-reflective electromagnetic field sheet of the fourth example. FIG. 13 shows the wiring of row voltage sensors according to the fourth example. FIG. 14 shows the wiring of column voltage sensors according to the fourth example. A low-reflective electromagnetic field sensor of the present example is realized by a mushroom-like metallic periodic structure that includes a metal patch and a via disposed at the center of the metal patch, like the sensor of the first example. Other configurations are identical to those of the first example and thus the explanation thereof is omitted.

As shown in FIG. 11, metal patches 51 are periodically disposed on a first layer on a surface of a plate dielectric 50. Specifically, the metal patches 51 are disposed in a lattice pattern, that is, in a row direction (horizontal direction) and a column direction (vertical direction). For example, metal patches 51(1), 51(2), 51(3) . . . are disposed in the first row while metal patches 51(1), 51(21), 51(31) . . . are disposed in the first column. The metal patches 51 are connected via resistors 55. A via 52 is provided at the center of the metal patch 51 as will be discussed later.

The metal patches 51 are sufficiently small relative to a wavelength λ of an electromagnetic wave to be measured, like the metal patch 21 of the first example. The length of one side of the metal patch 51 is ( 1/10)λ or less.

The dielectric 50 is thin and is made of materials such as polyimide. The dielectric 50 can be bent with flexibility.

As in the first example, a ground 54 that is a conductor serving as a second layer parallel to the first layer is provided with the dielectric 50 interposed between the ground 54 and the metal patch 51. The ground 54 is substantially identical in size to the dielectric 50. FIG. 12 shows the grand pattern of the low-reflective electromagnetic field sheet according to the fourth example.

The ground 54 is connected to the metal patch 51 via a conductor via 52 with the dielectric 50 interposed between the ground 54 and the metal patch 51. Specifically, the metal patch 51(1) is connected to the ground 54 via a via 52(1), the metal patch 51(2) is connected to the ground 54 via a via 52(2), and the metal patch 51(3) is connected to the ground 54 via a via 52(3).

Furthermore, row voltage sensor wires 57 in FIG. 13 have the dielectric 50 interposed between the ground 54 and the row voltage sensor wires 57. Moreover, column voltage sensor wires 67, row voltage sensors 58, and column voltage sensors 68 in FIG. 14 are provided on the back side of the dielectric 50 with the dielectric 50 interposed between the row voltage sensor wire 57 in FIG. 13 and the wires 67 and the sensors 58 and 68.

The row voltage sensor 58 is connected to the row voltage sensor wire 57 via a row voltage sensor via 56. The column voltage sensor 68 is directly connected to the column voltage sensor wire 67.

A conductor voltage sensor via 53 is provided on each end of the resistor 55. The voltage sensor via 53 penetrates the dielectric 50 and the ground 54 and is connected to the row voltage sensor 58 and the column voltage sensor 68 via the row voltage sensor wire 57 and the column voltage sensor wire 67. The ground 54 has a hole where the voltage sensor via 53 is inserted. This electrically disconnects the ground 54 and the voltage sensor via 53.

Specifically, for example, voltage sensor vias 53(1) and 53(2) are provided on the respective ends of the resistor 55(1) in the first row and the first column. The voltage sensor via 53(1) is connected to the row voltage sensor wire 57(1) and the column voltage sensor wire 67(1) while the voltage sensor via 53(2) is connected to a row voltage sensor wire 57(2) and a column voltage sensor wire 67(2). A row voltage sensor 58(1) is connected to the row voltage sensor wire 57(1) and 57(2) while a column voltage sensor 68(1) is connected to the column voltage sensor wire 67(1) and 67(2). Thus, both ends of the resistor 55(1) are respectively connected to the row voltage sensor 58(1) and the column voltage sensor 68(1).

Similarly, both ends of a resistor 55(2) in the first row and the second column are respectively connected to the row voltage sensor 58(1) and the column voltage sensor 68(2) while both ends of a resistor 55(3) are respectively connected to the row voltage sensor 58(1) and a column voltage sensor 68(3). Both ends of the resistor 55(21) in the second row and the first row are respectively connected to a row voltage sensor 58(2) and the column voltage sensor 68(1) while both ends of a resistor 55(31) in the third row and the first column are respectively connected to a row voltage sensor 58(3) and the column voltage sensor 68(1).

The row voltage sensor 58 detects a voltage induced to the resistor 55 in the same row, through the voltage sensor via 53. The column voltage sensor 68 detects a voltage induced to the resistor 55 in the same column, through the voltage sensor via 53. Specifically, for example, the row voltage sensor 58(1) detects a voltage induced to the resistors 55(1), 55(2), 55(3) . . . in the first row while the column voltage sensor 68(1) detects a voltage induced to the resistors 55(1), 55(21), 55(31) . . . in the first row. Thus, the row voltage sensor 58 and the column voltage sensor 68 identify the resistor 55 having received an induced voltage. In other words, the arrival direction of electromagnetic waves is identified.

Thus, in the fourth example, the row voltage sensor 58 detects the row that receives an induced voltage; meanwhile, the column voltage sensor 68 detects the column that receives an induced voltage, thereby detecting the position of the element having an induced voltage. In the fourth example, the number of voltage sensors can be smaller than that of the first example.

In the fourth example, any sensors capable of detecting the energy of elements may be used instead of the voltage detecting sensor as in the first embodiment.

In this explanation, the resistors extending in the horizontal direction of FIG. 11, that is, the resistors horizontally connecting the metal patches 51 are illustrated for the sake of simplification. For example, the voltage sensor via 53, the row voltage sensor wire 57, the row voltage sensor 58, the column voltage sensor wire 67, and the column voltage sensor 68 were described for the resistor 55(1) and so on. Similarly, the voltage sensor via, the row voltage sensor wire, the row voltage sensor, the column voltage sensor wire, and the column voltage sensor (any of them are not shown) can be provided for the vertically extending resistors such as the resistor 55(11). Alternatively, the vertically extending resistors may not be provided.

### Fifth Example

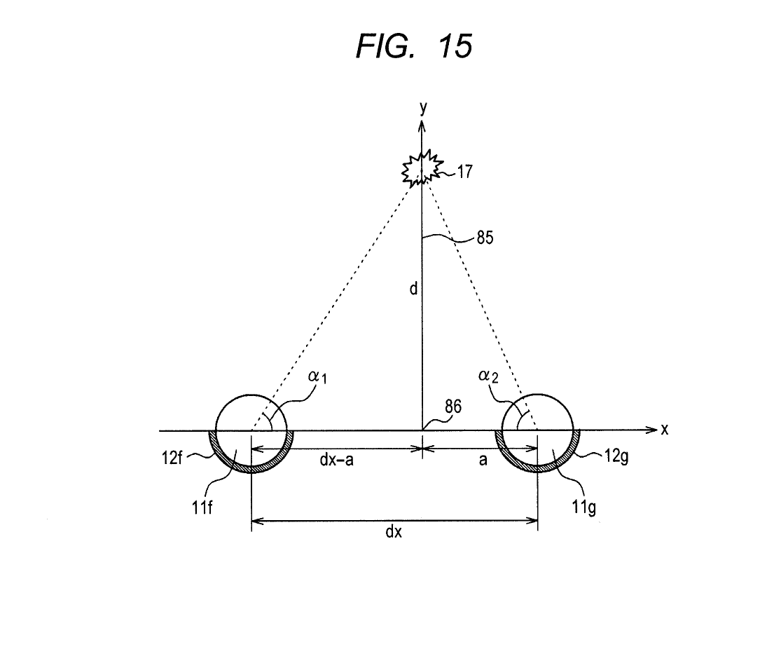

Referring to FIG. 15, a fifth example for three-dimensionally specifying the position of the emission source of electromagnetic waves will be described below. FIG. 15 shows the principal part of a three-dimensional electromagnetic field measuring device according to a fifth example.

In the fifth example, unlike in the first example, a lens unit 11 includes a plurality of lenses that directly receive electromagnetic waves from noise sources. In the example of FIG. 15, the lens unit 11 includes two Luneburg lenses 11f and 11g that detect a distance of the source of noise. Other configurations are identical to those of the first example and thus the explanation thereof is omitted.

As shown in FIG. 15, the hemisphere faces of the lenses 11f and 11g on the electromagnetic wave incident side are opposed to a noise source 17. Sensor units 12f and 12g are provided on the opposite hemisphere faces of the lenses 11f and 11g from the electromagnetic wave incident side. Reference character dx denotes a distance between the lenses 11f and 11g, specifically, a distance between the center of the lens 11f and the center of the lens 11g. Reference character d denotes a distance between the noise source 17 and the installation positions of the lenses 11f and 11g, that is, the length of a perpendicular 85 drawn from the noise source 17 with respect to a straight line connecting the center of the lens 11f and the center of the lens 11g. Reference numeral 86 denotes the intersection point of the perpendicular 85 with the straight line. A distance between center of the lens 11f and the intersection point 86 is expressed as dx-a where a is a distance between the center of the lens 11g and the intersection point 86.

The distance d is expressed by the following formula: where α₁ is the angle of an electromagnetic wave detected in the lens 11f from the noise source 17, and α₂ is the angle of an electromagnetic wave detected in the lens 11g.

$$\begin{matrix}tan {α}_{1} = \frac{d}{d x - a} & [ Formula 2 ] \\ tan {α}_{2} = \frac{d}{a} & [ Formula 3 ]\end{matrix}$$

Equation 3 is solved for a and is substituted into Equation 2 to obtain the following equation: where d is a distance to the noise source 17.

$$d = \frac{tan {α}_{1} tan {α}_{2}}{tan {α}_{1} + tan {α}_{2}} dx \qquad [ Equation 4 ]$$

If a spherical Luneburg lens is used, information on an elevation angle and an azimuth angle is provided as detected angles. Thus, the position of the noise source 17 can be three-dimensionally detected by the two lenses 11f and 11g, the two sensor units 12f and 12g, and a processing unit 13. In the case of a two-dimensional display unit, for example, the two-dimensional position (the arrival direction of noise) of the noise source 17 is displayed as well as a numerical value (e.g., 15 m) representing a distance to the noise source 17.

In the present example, the two lenses and the two sensor units are used. At least three lenses and at least three sensor units may be used instead.

The fifth example makes it possible to detect the arrival direction of an electromagnetic wave, that is, the two-dimensional position of the emission source of electromagnetic waves and a distance to the emission source of electromagnetic waves, thereby easily specifying the three-dimensional position of the emission source of electromagnetic waves.

The present invention is not limited to the foregoing embodiment. It is needless to say that various changes can be made within the scope of the invention.

In the embodiment, the emission position of electromagnetic waves and the level of energy are displayed on a background captured by a camera. Alternatively, the relative emission position of electromagnetic waves and the level of energy can be displayed without using a background captured by a camera.

Moreover, the level of energy of electromagnetic waves may not be displayed. In other words, only the emission position of electromagnetic waves with energy having a predetermined value or more may be displayed.

### REFERENCE SIGNS LIST

11 . . . emission direction separation unit,
11a . . . Luneburg lens,
11b . . . aspheric lens,
11c . . . aspheric lens,
11d . . . parabolic antenna,
12 . . . sensor unit,
12d . . . transmission line,
13 . . . processing unit,
13d . . . transmission line,
14 . . . camera unit,
14d . . . transmission line,
15 . . . display unit,
16 . . . measuring object,
16a . . . measuring object image,
17 . . . noise source,
17a . . . noise source image,
18 . . . electromagnetic wave,
20 . . . dielectric,
21 . . . metal patch,
22 . . . via,
24 . . . ground,
25 . . . resistor,
26 . . . voltage sensor via,
27 . . . voltage sensor,
32 . . . electromagnetic wave,
32f . . . focus,
33 . . . electromagnetic wave,
33f . . . focus,
41 . . . theoretical value,
42 . . . set value,
50 . . . dielectric,
51 . . . metal patch,
52 . . . via,
53 . . . voltage sensor via,
54 . . . ground,
55 . . . resistor,
56 . . . row voltage sensor via,
57 . . . row voltage sensor wire,
58 . . . row voltage sensor,
67 . . . column voltage sensor wire,
68 . . . column voltage sensor,
81 . . . camera (lens center position),
81a . . . maximum field of view of a camera at the center of the lens,
81b . . . image captured by the camera at the center of the lens,
82 . . . camera (actual position),
82a . . . actual maximum field of view,
82b . . . actual image,
83 . . . camera position correction,
84 . . . maximum viewing angle θ,
85 . . . perpendicular,
86 . . . intersection

1. An electromagnetic wave visualizing system comprising:
an emission direction separation unit that changes an emission direction of an electromagnetic wave according to an incoming direction of the electromagnetic wave;
a plurality of sensors, each detecting energy of an electromagnetic wave emitted from the emission direction separation unit and outputting a sensing signal having strength corresponding to the detected energy;
a processing unit capable of receiving the sensing signal from each of the sensors, the processing unit outputting a display signal when receiving the sensing signal from the sensor, the display signal containing information on an arrival direction of an electromagnetic wave according to the sensor having transmitted the sensing signal; and
a display unit capable of displaying the arrival directions of electromagnetic waves, the display unit displaying the arrival direction of an electromagnetic wave when receiving the display signal.

2. The electromagnetic wave visualizing system according to claim 1, wherein the display unit displays the arrival direction of an electromagnetic wave according to the strength of the sensing signal when displaying the arrival direction of the electromagnetic wave according to the sensor having transmitted the sensing signal.

3. The electromagnetic wave visualizing system according to claim 1, wherein the processing unit outputs the display signal containing the information on the arrival direction of an electromagnetic wave according to the sensor having transmitted the sensing signal, if the sensing signal received from the sensor is so strong as to reach at least a predetermined value.

4. The electromagnetic wave visualizing system according to claim 1, wherein the emission direction separation unit includes an electromagnetic wave lens.

5. The electromagnetic wave visualizing system according to claim 4, wherein the electromagnetic wave lens includes a Luneburg lens, and
each of the sensors includes a flexible low-reflective electromagnetic field sheet.

6. The electromagnetic wave visualizing system according to claim 4, wherein the electromagnetic wave lens includes a plurality of aspheric lenses arranged in series along the incoming directions of electromagnetic waves.

7. The electromagnetic wave visualizing system according to claim 1, wherein the emission direction separation unit includes a plurality of antennas that directly receive electromagnetic waves.

8. The electromagnetic wave visualizing system according to claim 1, further comprising a camera unit that captures an image of a measuring object and outputs an image signal of the image,
wherein the processing unit outputs the display signal when receiving the image signal from the camera unit and the sensing signal from the sensor, the display signal containing information on the arrival direction of an electromagnetic wave according to the image signal and the sensor having transmitted the sensing signal, and
the display unit displays the arrival direction of the electromagnetic wave on the image of the image signal when receiving the display signal.

9. The electromagnetic wave visualizing system according to claim 1, wherein the processing unit has a table in which positions of the sensors are associated with the arrival directions of electromagnetic waves, and the processing unit obtains arrival direction information on electromagnetic waves with reference to the table based on position information on the sensor having outputted the sensing signal.

10. The electromagnetic wave visualizing system according to claim 1, wherein the emission direction separation unit is divided into a plurality of units separated from one another,
the processing unit determines, based on the sensing signals from the sensors, detected angles of electromagnetic waves entering the emission direction separation units from an emission source of the electromagnetic waves, and outputs a display signal containing three-dimensional position information on the emission source of the electromagnetic waves, and
the display unit displays a three-dimensional position of the emission source of electromagnetic waves.
